(19) United States
(12) Patent Application Publication
(10) Pub. No.: US 2011/0308563 A1
(43) Pub. Date: Dec. 22, 2011

(54) FLEXIBLE PHOTOVOLTAIC MODULES IN A CONTINUOUS ROLL

(75) Inventor: Paul Shufflebotham, San Jose, CA (US)

(73) Assignee: MIASOLE, Santa Clara, CA (US)

(21) Appl. No.: 12/820,415

(22) Filed: Jun. 22, 2010

(51) Int. Cl. H01L 31/042; B32B 38/04; B32B 37/02

(52) U.S. Cl. 136/244; 156/60; 156/64

(57) ABSTRACT

Provided are novel flexible photovoltaic assemblies and installation techniques. The assemblies include multiple flexible photovoltaic (PV) modules that are electrically connected and individually sealed. The modules may be sealed using a flexible material that provides protection from the environment and/or mechanical support to the cells and modules. These assemblies can be bent and even rolled. Each PV module is individually sealed with a cut-off area is provided between two consecutive modules for separating the modules. The design allows separating any number of modules from a roll without compromising any module. The modules are electrically interconnected with each other while in the roll. As such, when a set of modules is separated from a roll, all modules in a set are electrically interconnected as well as having an integral mechanical structure. The assemblies allow easy cut-to-fit installation on rooftops or other points of installation.

### BACKGROUND

Photovoltaic (PV) technology is being rapidly adopted to generate electricity from solar energy. It used to provide electricity for local uses and often to power an electrical grid and may be used on vehicles, buildings, or as standalone solar arrays.

PV cells are basic units of this technology and are typically interconnected into a PV module, which may be an individual building block of a PV array. A conventional PV module requires individual handling, installation, and electrical interconnection with other modules and electrical systems of an array. Often the modules require complex mounting structures for support.

Rigid materials and structures are used in construction of conventional PV modules. For example, rigid silica glass is one of the most common materials for frontside protection of PV modules. In addition, modules often have rigid frames. The construction and installation of such modules substantially increases the cost of solar power generation making it less competitive in comparison to other alternatives, such as fossil fuels.

### SUMMARY

Provided are novel flexible photovoltaic assemblies and installation techniques. The assemblies include multiple flexible photovoltaic (PV) modules that are electrically connected and individually sealed. The modules may be sealed using a flexible material that provides protection from the environment and/or mechanical support to the cells and modules. These assemblies can be bent and even rolled. Each PV module is individually sealed with a cut-off area is provided between two consecutive modules for separating the modules. The design allows separating any number of modules from a roll without compromising any module. The modules are electrically interconnected with each other while in the roll. As such, when a set of modules is separated from a roll, all modules in a set are electrically interconnected as well as having an integral mechanical structure. The assemblies allow easy cut-to-fit installation on rooftops or other points of installation.

In certain embodiments, a roll for fabricating a photovoltaic (PV) array includes a flexible continuous backside sheet, a transparent flexible continuous frontside sheet, a row of individually sealed PV modules extending along the length of the roll and including at least two PV modules disposed between the backside sheet and the frontside sheet. The roll also includes a cut-off area located between the two PV modules and a module connector that passes through the cut-off area and electrically interconnects the two PV modules. The cut-off area allows separation of the two PV modules, while maintaining the individual seals of each PV module. The row may include at least ten individually sealed and electrically interconnected PV modules. Any number of the PV modules can be individually separated from the row without losing an individual seal of any of the PV modules. A roll may include a second row of PV modules such that the same backside and frontside sheets provide individual seals to each PV module in the second row. There may be cut-off areas located between the first row and the second row.

In certain embodiments, a module connector electrically interconnects the two PV modules in parallel. The module connector may be configured to limit the electrical current passing through the connector. The module connector may be also configured to prevent electrical shorts when the two PV modules are separated by, for example, cutting. In certain embodiments, the module connector includes two bus wires that are spaced apart by at least about 2 inches while passing through the cut-off area.

In certain embodiments, the cut-off area between two PV modules is at least about 2 inches wide. The cut-off area may include scores that are partially cut through the frontside sheet and the backside sheet. The cut-off area can be spaced apart from each of the two PV modules by at least 0.5 inches. The cut-off area may be identified on the frontside sheet with two line markings extending across the row.

A roll may include a sealant disposed between the frontside sheet and the backside sheet around the entire perimeter of each PV module at least in the area between the PV modules and the cut-off area. The transparent flexible continuous frontside sheet may include one or more of the following materials: polyethylene terephthalate (PET), polyethylene naphthalate (PEN), and a transparent metal oxide, such as calcium oxide, aluminum oxide, and zinc oxide. The thickness of the frontside sheet can be between about 3 mils and 30 mils. In certain embodiments, the flexible continuous backside sheet includes an aluminum sheet that can be offset from the cut-off area. The thickness of the backside sheet can be between about 5 mils and 80 mils. The backside sheet can be at least 12 inches wide.

In certain embodiments, each PV module in the roll is configured to provide electrical power output at a voltage of between about 10V and 30V at typical operating conditions. The roll may include a plurality of mounting features. For example, each PV module may have at least four mounting features located at each corner of the PV module. In certain embodiments, the roll includes bypass diodes, inverters, and/or DC/DC converters.

Provided also is a method of fabricating a roll that includes a row of multiple flexible photovoltaic (PV) modules. This method may involve providing a first flexible continuous sheet, positioning at least two PV modules onto the first sheet, and installing a module connector to establish electrical connection between the two PV modules. The method may then involve placing a second flexible continuous sheet over the first sheet and the two PV modules and establishing a seal between the first sheet and the second sheet around each of the two PV modules to individually insulate each PV module. The method may also include dispensing a sealant material onto the first sheet around the perimeter of each of the two PV cells prior to placing the second sheet. Sealing may also include laminating an assembly that includes the first sheet, two PV panels, and second sheet. In certain embodiments, the lamination includes applying heat and pressure to this assembly. The method may also involve arranging and electrically interconnecting individual PV cells in the two PV modules on the first sheet.

Provided also is a method of installing a photovoltaic (PV) array using a roll described above. The method may include providing the roll, identifying a number of PV modules in a first set, and identifying a cut-off area on the roll separated by the number of PV modules in the first set from a free end of the roll. The method may continue with separating the first set of PV modules from the roll and installing the first set of PV modules into the PV array. These operations may be repeated for additional sets to complete the PV array and electrically interconnecting at least two sets with an array connector. The array connector is configured to electrically connect to a portion of the module connector remaining at the end module of the first set of PV modules after separating of the first set of PV modules. The array connector may be configured to electrically insulate the portion of the module connector. This method may also involve electrically insulating at least a portion of a cut-off area an end module of the first set of PV modules.

These and other aspects of the invention are described further below with reference to the figures.

### BRIEF DESCRIPTION OF THE DRAWINGS

FIG. 1 is a schematic representation of a photovoltaic (PV) module in accordance with certain embodiments.

FIG. 2 is a process flowchart corresponding to one example of a technique for fabricating a roll containing multiple PV modules.

FIG. 3A illustrates a schematic top view of a portion of a roll of PV modules in accordance with certain embodiments.

FIG. 3B illustrates a schematic electrical diagram showing interconnection of three PV modules in a roll and a relative position of the bus wires in accordance with certain embodiments.

FIG. 3C illustrates a schematic side cross-sectional view of a cut-off area exemplifying sealing details in accordance with certain embodiments.

FIG. 4 is a process flowchart corresponding to one example of a technique for installing a PV array from a roll containing multiple flexible PV modules.

FIG. 5 illustrates an example of a PV array containing multiple sets of PV modules.

### DETAILED DESCRIPTION OF EXAMPLE EMBODIMENTS

In the following description, numerous specific details are set forth in order to provide a thorough understanding of the present invention. The present invention may be practiced without some or all of these specific details. In other instances, well known process operations have not been described in detail to not unnecessarily obscure the present invention. While the invention will be described in conjunction with the specific embodiments, it will be understood that it is not intended to limit the invention to the embodiments.

### Introduction

Provided herein are various design examples of a roll containing multiple photovoltaic (PV) modules, examples of techniques for fabricating such roll, and examples of techniques of installing a PV array using such roll. In certain embodiments, a roll includes flexible continuous backside and frontside sheets that provide an integral common seal of the modules in the set and/or individual seals to each of multiple PV modules. The modules are arranged in one or more rows between the two sheets. The roll also includes cut-off areas located between PV modules. The cut-off areas allow, for example, separating two consecutive PV modules in a row while maintaining their individual seals. When a roll has multiple rows of PV modules, cut-off areas may extend between the rows. Furthermore, all PV modules in a row may be electrically interconnected with each other using module connectors.

These roll designs allow installers to separate (e.g., cut-off) a set containing multiple PV modules from a roll instead of handling individual modules. All modules in the set are mechanically integrated, sharing the same continuous backside and frontside sheets. Furthermore, all modules in the set are electrically interconnected with each other with the module connectors installed during fabrication of the roll and sealed between the two continuous sheets. An installer may use any number of PV modules in each set, which may be driven by installation capabilities or possible arrangements of PV modules in the installed array.

Integrating multiple PV modules into rolls reduces complexity and costs of fabrication and installation of PV modules. PV arrays installed using such rolls tend to be more robust during their operation because fewer disjoined structures (i.e., sets of multiple modules v. individual modules) are used. There are fewer exposed edges in such arrays for moisture to penetrate through. Set sizes can be customized in the field to fit, for example, a given rooftop configuration or other installation requirements rather than being preset during fabrication. This can provide additional flexibility during installation and substantially reduce installation costs. Furthermore, electrical interconnections within each set are factory installed and sealed. The sets, which are integral mechanical structures that share the same backside and frontside sheets, require less mounting hardware than conventional separate modules and provide support to the modules sealed within.

In the context of this document, a “PV module” is defined as a basic unit of electrically interconnected PV cells sealed together within the same structure. A PV module has a predetermined voltage output and other operating characteristics. The frontside side of a PV module is made of a transparent material to allow sun light to reach PV cells inside the module. The seal is provided to insulate the cells from environmental conditions. PV modules are sometimes also referred to as PV panels.

A “PV roll” is defined as a continuous web containing multiple PV modules arranged in one or more rows. A number of modules in the roll may be two or more. In certain embodiments, a roll may include ten or more modules. The modules are individually sealed between two flexible sheets of the web, i.e., the frontside sheet and the backside sheet. In certain embodiments, all PV modules in one row are electrically interconnected to each other. A roll can include multiple modules that are not electrically connected. The connections to the modules are formed later, for example, during installation. A roll contains cut-off areas between the modules that allow separating one or more modules from the roll without loosing or compromising individual seals of the modules.

A “PV set” is defined as a collection of PV modules separated (e.g., cut) from a single PV roll. A PV set has a common continuous backside sheet and a common continuous frontside sheet that form an integral mechanical structure. In certain embodiments, the common continuous sheets also form an integral seal, that is a seal around one or more edges of the set. A number of modules in a set length may be determined by array configuration, installation requirements, and other factors. In many embodiments, all PV modules in a set are electrically interconnected, at least at the time the set is separated from the roll. The modules in a set may remain interconnected after installation of the array. In certain embodiments, not all modules in a set are electrically connected after installation. For example, a number of modules in a set may exceed a predetermined current value (where the modules in the set are interconnected in parallel) and a sub-set of modules may need to be electrically disconnected from the rest of the set. However, both sub-sets may share common frontside and backside sheets and a common mechanical structure. In certain embodiments, a roll may be provided with sub-sets of modules that share a common mechanical structure but are not electrically interconnected. As discussed further below, an installer may interconnect the sub-sets at installation.

A “PV array” is defined as an arrangement of one or more PV sets or rolls that are typically installed in the same location (e.g., a rooftop). The PV sets are electrically interconnected with each other and other elements of the overall power generation system, such as batteries, inverters, powered devices, and/or electrical grids. Arrays generally include one or more PV sets, mounting hardware to support the PV sets, and array connectors to electrically interconnect the PV sets and other electrical devices. In many cases, an array may include one or more entire PV rolls.

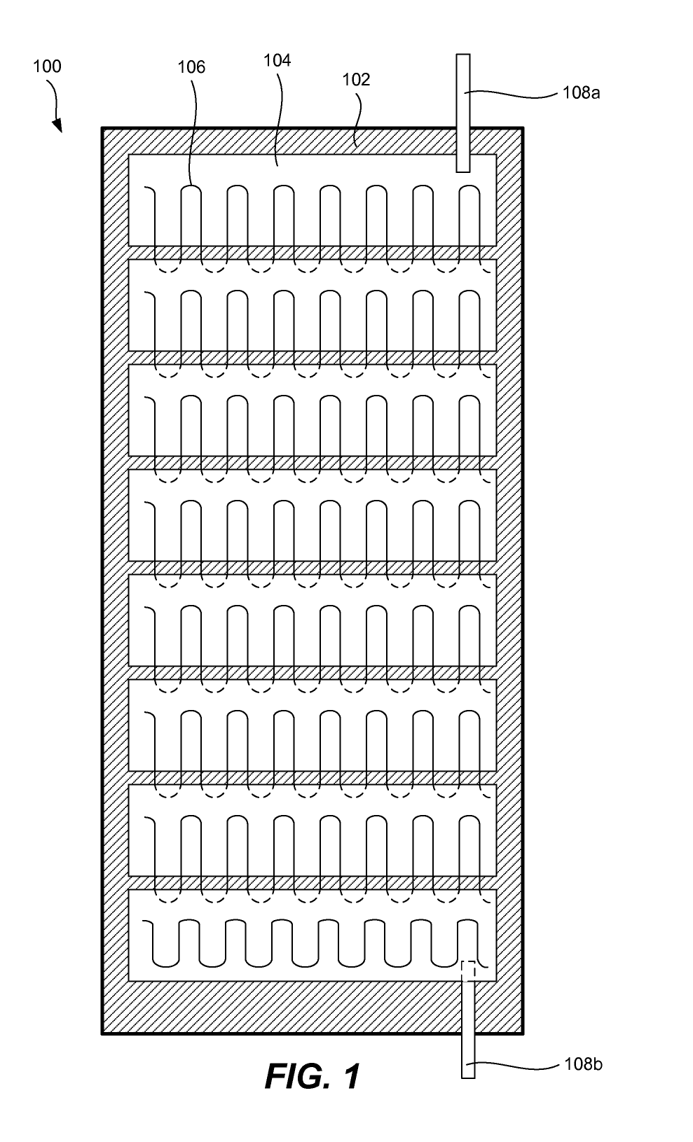

FIG. 1 is a schematic representation of a PV module 100 in accordance with certain embodiments. The module 100 includes one or more PV cells 104 that are configured to convert solar energy into an electrical current. Often individual PV cells do not provide an adequate operating voltage. For example, a typical operating voltage for a Copper-Indium-Gallium-Selenide (CIGS) cell is between 0.4V and 0.7V, while a module design may dictate an operating voltage of between about 15V and 30V. In these situations, PV cells may be electrically interconnected in series in the module. In certain embodiments, a module includes at least ten individual cells interconnected in series with each other or, more specifically, at least twenty cells, or even forty cells.

Various interconnecting techniques are available, e.g., monolithic and non-monolithic. In monolithic interconnection schemes, interconnections are made between cells directly on the shared substrate, e.g., during thin film deposition. In non-monolithic interconnection processing schemes, individual cells are fabricated and strung together. For example, a PV cell may have an electrical wire 106 that contacts one electrical terminal of the cell, such as a transparent conducting oxide (TCO) layer. The wire extends outside of the cell's perimeter and makes an electrical contact with a portion of another cell, such as a conductive backside substrate. This wire 106 may also be used to provide more uniform current distribution and collection from one or both contact portions. Other non-monolithic wiring arrangements may also be used.

In certain embodiments, an operating voltage of the module is between about 10V and 30V. The voltage is measured between two electrical leads 108a and 108b, which also serve to electrically interconnect the module 100 with other modules provided in the same row of the roll. A module may be configured to pass an electrical current of at least about 1 A or, more specifically, at least about 2 A, or even at least about 5 A, or at least about 10A. Voltage and current ratings may be determined by interconnection schemes of the module in the roll, e.g., in series, parallel, or a combination of in series and parallel interconnections. However, this current does not need to pass through PV cells of the module. A module may be equipped with an electrical bypass circuit (not shown) that allows passing higher currents through the module than what is acceptable for the PV cells.

In certain embodiments, PV cells 104 are prearranged into PV modules 100 prior to fabrication of a PV roll. Modules are then provided into a roll fabrication process. In order to maintain alignment of the cells in a module, one or more support sheets 102 may be used. For example, a support sheet 102 may have an adhesive backing. In other embodiments, cells may be laminated between two sheets prior to being integrated between the frontside and backside sheet of the roll, e.g., two support sheets are used. A support sheet may be used as a temporary support and removed during fabrication of a roll or may become a part of the roll.

In other embodiments, PV cells are arranged into modules during fabrication of the roll. In this case, individual PV cells may be positioned directly onto a first continuous sheet without using a separate support sheet. The first continuous sheet may serves as a support sheet in these embodiments. PV cells many be temporary supported by features provided on the first sheet (e.g., adhesive backing) and/or features of the equipment (e.g., magnetic alignment). Permanent support to the PV modules may be provided by lamination of the first sheet to the second sheet.

PV cells must be sufficiently flexible and/or small to allow the web containing the cells to bend and form a roll. Any type of PV cells may be used in the assemblies described herein, including crystalline and thin film PV cells. Examples of PV cells include but are not limited to Cadmium-Telluride (Cd—Te) cells, Copper-Indium-Gallium-Selenide (CIGS) cells, amorphous Silicon (a-Si) cells, micro-crystalline Silicon, and crystalline Silicon (c-Si) cells. These cells have p-n junctions that may be formed on a metallic substrate, such as stainless steel, titanium, copper, aluminum, beryllium, and the like. It should be noted that, in certain embodiments, the PV cells may have multiple p-n junctions, for example, tandem or triple junction cells. The substrate may be relatively thin, e.g., less than or equal to about 2-10 mils. Typically, a stack includes a back electrical contact layer between the substrate and the p-n junction. Examples of materials that can be used for a back electrical contact layer include molybdenum, niobium, copper, silver, etc. A top transparent electrode layer is positioned on the p-n junction. In certain embodiments, the top transparent electrode layer is a TCO, for example, zinc oxide, aluminum-doped zinc oxide (AZO), indium tin oxide (ITO) and gallium doped zinc oxide.

In certain embodiments, PV cells are rigid but sufficiently small in at least one direction, e.g., along the length of the web. Such PV cells are interconnected with flexible connectors providing flexibility to the PV modules and allowing the web to bend and form a roll.

FIG. 1 provides an example of PV cells arranged within a PV module. Other arrangements are within the scope of the embodiments described herein. For example, there may be multiple rows of PV cells within the module. The electrical connection configuration may also vary. For example, the PV cells in a PV module may be connected in series (as in FIG. 1), in parallel, or in series/parallel, with multiple strings of cells wired in parallel.

### Fabricating a Roll

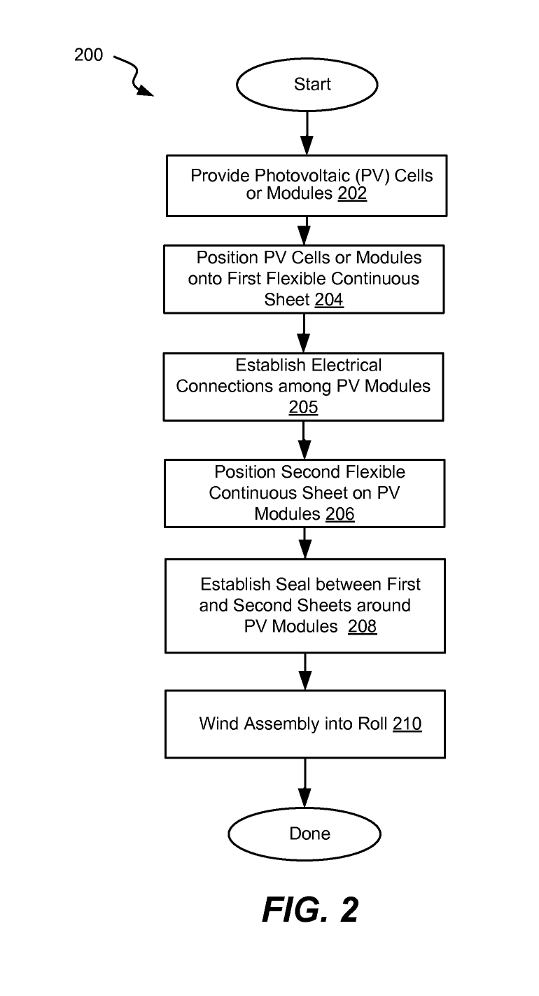

FIG. 2 is a process flowchart corresponding to one example of a technique for fabricating a continuous roll with multiple PV modules. The process 200 may start with providing PV modules or PV cells in operation 202. Examples of PV modules and cells are described above. Unlike conventional PV modules that are used for installation in a field, PV modules or cells provided in operation 202 do not necessarily need to be sealed and/or electrically insulated. Sometimes such modules or cells are referred to as “bare modules” or “bare cells.” For example, pre-assembled unsealed modules (e.g., a set of interconnected PV cells arranged on a support sheet as described above) may be used. Alternatively, PV cells may be used directly in operation 202 without being pre-assembled into modules. Furthermore, integrated pre-assembled and sealed modules (e.g., modules that can be used as standalone modules) can be used. In this latter embodiment, the modules may not need to be further individually sealed, however a roll may be used for common mechanical support and electrical interconnections, as well as providing a seal around the sets of modules in the roll.

The PV modules or cells are then positioned onto a first flexible continuous sheet in operation 204. The first sheet could be either a backside sheet or a transparent frontside sheet. If the backside sheet is used in operation 204, then the frontside sheet will be used in operation 206 and vice versa. In certain embodiments, the same sheet may be used in both operations. For example, a sheet that is twice as wide as a resulting web may be provided in operation 204. Such a sheet is then folded in half to cover and seal the PV modules. In this approach, the folding edge itself provides a seal. It should be noted that a double-wide sheet can be fabricated from two sheets of different materials (e.g., one transparent sheet and one non-transparent) that are integrated together prior to operation 204.

Examples of materials used in flexible sheets (the first and second sheets) include polyethylene, polyethylene terephthalate (PET), polypropylene, polybutylene, polybutylene terephthalate (PBT), polyphenylene oxide (PPO), polyphenylene sulfide (PPS) polystyrene, polycarbonates (PC), ethylene-vinyl acetate (EVA), fluoropolymers (e.g., polyvinyl fluoride (PVF), polyvinylidene fluoride (PVDF), ethylene-terafluoethylene (ETFE), fluorinated ethylene-propylene (FEP), perfluoroalkoxy (PFA) and polychlorotrifluoroethane (PCTFE)), acrylics (e.g., poly(methyl methacrylate)), silicones (e.g., silicone polyesters), polyvinyl chloride (PVC), as well as multilayer laminates and co-extrusions, such as PET/EVA laminates or co-extrusions. A typical thickness of such sheets is between about 3 mils and 40 mils or, more specifically, between about 4 mils and 12 mils. In general, both sheets need to be sufficiently flexible to allow the web to bend and to form a roll.

Both first and second sheets should be good moisture barriers. In certain embodiments, a water vapor transmission rate (WVTR) of the sheets is no more than 10⁻² g/m²/day at 85° C. and 85% relative humidity (RH) or, more specifically, no more than 10⁻³ g/m²/day at 85° C. and 85% RH. This test is sometimes referred to as a “damp heat” test. In certain embodiments, the first and/or second sheet includes a stack of multiple layers, one of which provides moisture barrier properties for the entire stack. For example, a pinhole-free metallic material, such as a foil made of aluminum, copper, palladium, titanium, gold, silver, iron, molybdenum, stainless steel, steel, zinc, and alloys thereof (e.g., brass), may be used as an intermediate layer. The foil may be at least about 17 micrometers thick or, more specifically, at least about 25 micrometers thick and even at least about 50 micrometers thick. In certain embodiments, the foil is electrically isolated from the photovoltaic cells as well as from the frontside and backside sheets. In some embodiments, the foil sheets corresponding to each of the PV modules are offset from the cut-off areas and edges of the roll (i.e., inset from the edges of the resulting module sets) to avoid the need for external grounding of these foil sheets.

In certain embodiments, an encapsulant is used to fill voids between a frontside sheet and PV modules. An encapsulant may be also used between a backside sheet and PV modules. Examples of encapsulant materials include non-olefin thermoplastic polymers or thermal polymer olefin (TPO), such as polyethylene (e.g., a linear low density polyethylene, a transparent or translucent heat-resistant polyolefin resin available from Dai Nippon Printing (DNP)), polypropylene, polybutylene, polyethylene terephthalate (PET), polybutylene terephthalate (PBT), polystyrene, polycarbonates, fluoropolymers, acrylics, ionomers, silicones, and combinations thereof. Other suitable bulk encapsulants include various SURLYN® thermoplastic ionomeric resin grades (e.g., PV4000 or equivalent), and SENTRY GLASS® laminate interlayer available from DuPont, and GENIOMER® 145 thermoplastic silicone elastomer available from Wacker Chemie. An encapsulant may include an ultraviolet absorber, a photo-stabilizer, and/or an antioxidant (e.g., phenol, amine, sulfur, and phosphoric acid antioxidants). If encapsulant is used between the first sheet and PV cells, then it is introduced prior to operation 204.

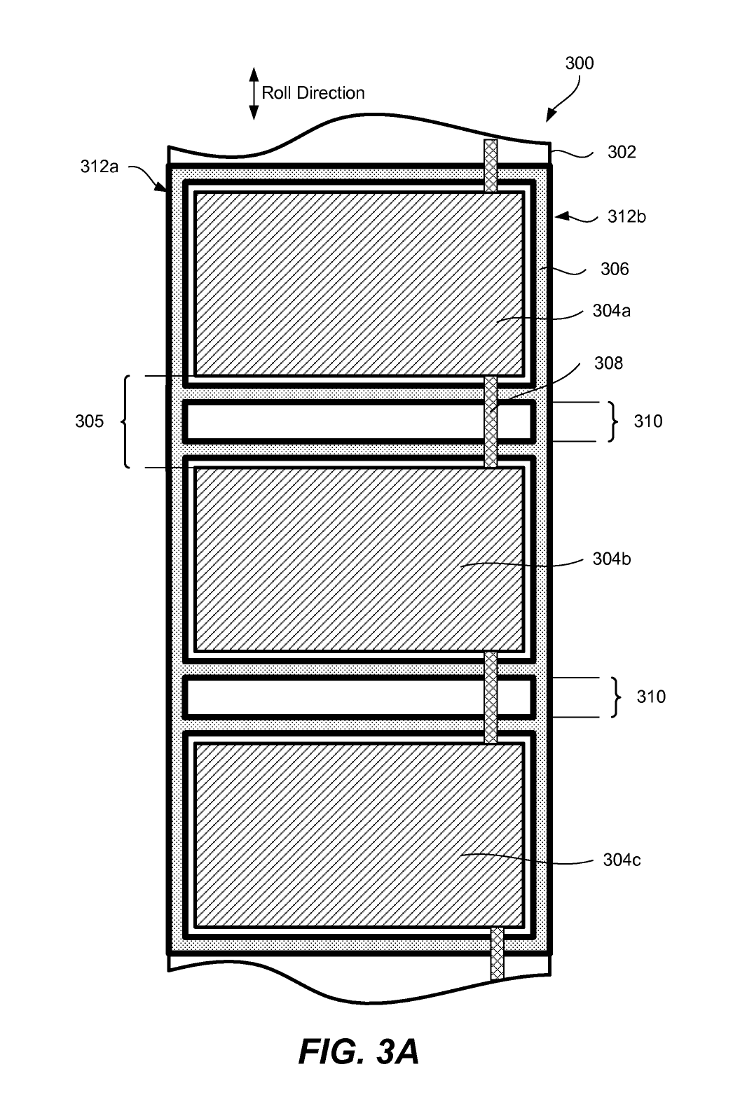

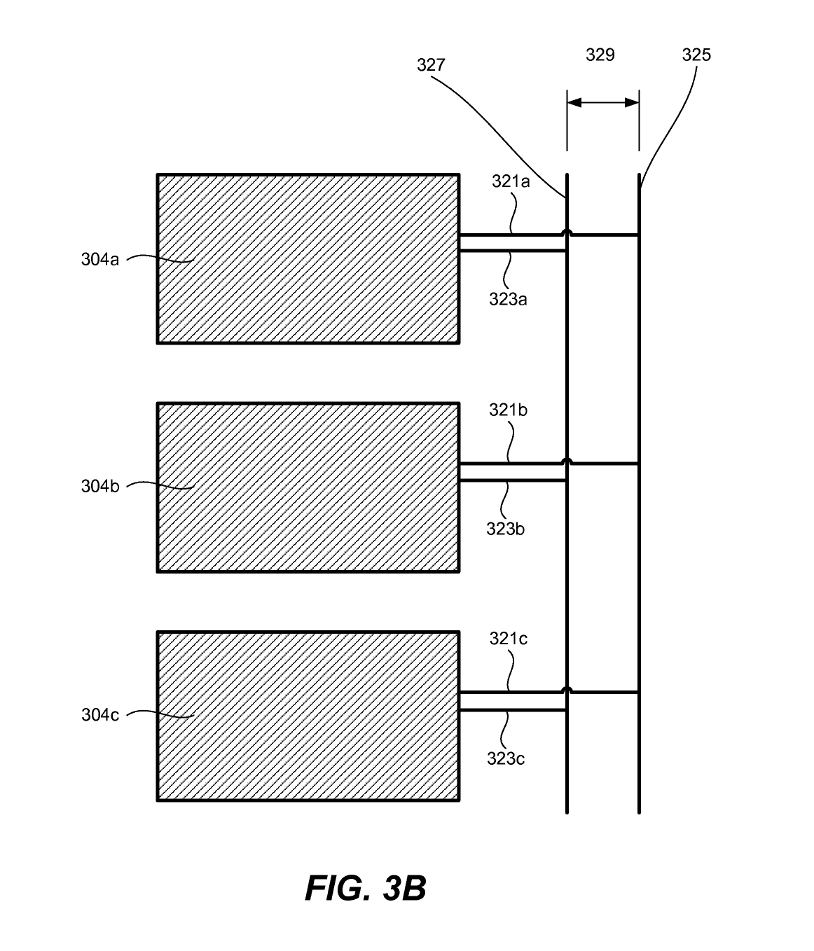

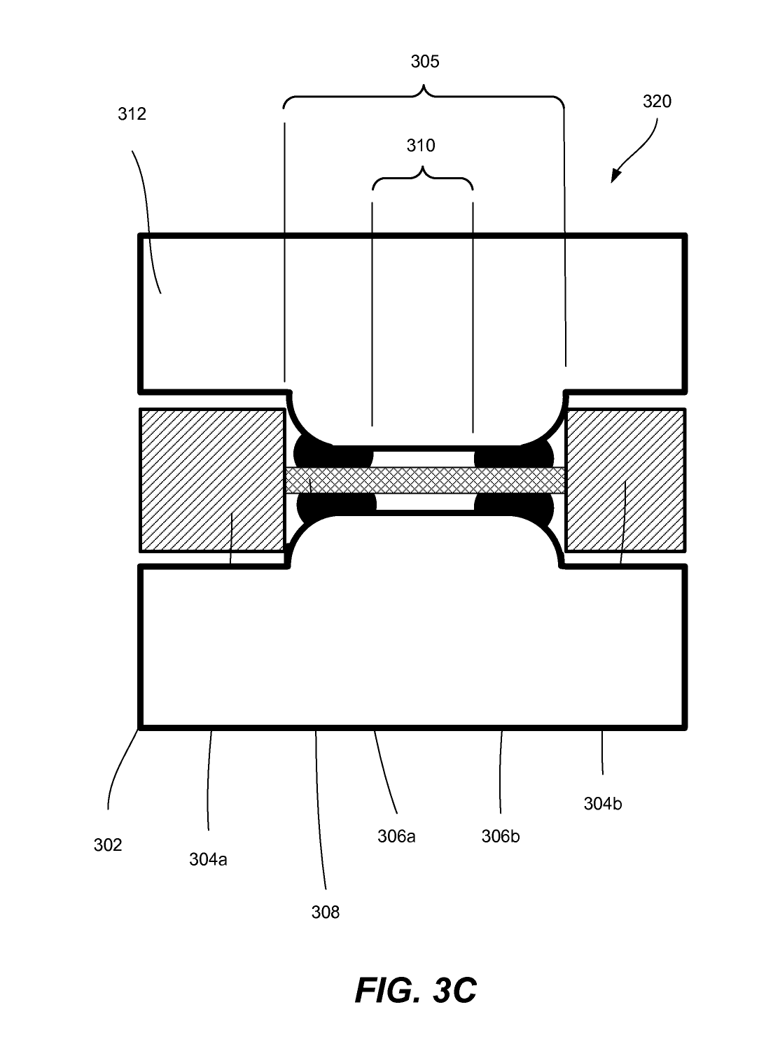

In operation 204, PV modules or cells are aligned on the first sheet to provide a sealing area around each module. At least a portion of the sealing area should be away from existing edges (i.e., the edges of the web) and cut-off areas in between modules. The alignment and position of these elements will now be explained in the context of FIG. 3A, which illustrates a schematic top view of a portion of a roll during its fabrication (i.e., prior to installation of the second sheet) in accordance with certain embodiments. Three PV modules 304a-304c are arranged in a row on a first sheet 302 and spaced apart by a distance 305. The spacing 305 between the modules 304a-304c includes a cut-off area 310 and a sealing area 306. In certain embodiments, the spacing is between about 0.5 inches and 10 inches or, more specifically between about 1 inch and 5 inches or, even more specifically, between about 1 inch and 2 inches. The modules 304a-304c are also spaced apart from both edges 312a and 312b of the first sheet 302 to accommodate the sealing area 306. In certain embodiments, the width of the sealing area 306 is between about 0.125 inches and 2 inches or, more specifically between about 0.25 inches and 1 inch or, even more specifically, between about 0.5 inches and 1 inch. The sealing area 306 generally extends around the entire perimeter of each module. In many embodiments, the seal in the sealing area 306 remains intact around a module even when the adjacent cut-off area is cut during separation from the roll.

Cut-off areas 310 are located between the modules 304a-304c to allow separating one or more modules from the remainder of the roll to form a set. In certain embodiments, cut-off areas 310 are at least 2 inches wide. In general, cut-off areas should be sufficiently wide to allow an installer to separate two modules without comprising the seal of either module. At the same time, cut-off areas should be sufficiently small to maximize an operational surface area of the panels.

FIG. 3A illustrates only one row of PV modules 304a-304c arranged on the first sheet 302. However, it should be understood that multiple rows of PV modules may be integrated into the same web. In other embodiments, a web has two, three, four, and even a greater number of rows. In general, this number is determined by dimensions of PV modules, a width of the web, and capabilities of processing and installation equipment. If multiple rows are used, cut-off areas similar to ones described above are provided between the rows. These web-direction cut-off areas allow creating, for example, single-row sets, or in combination with other cut-off areas, allow creating, for example, sets that have an L-shape, U-shape, or O-shape.

While FIG. 3A depicts cut-off areas between every pair of adjacent PV modules, in certain embodiments, fewer cut-off areas are provided, e.g., only between every two, three, or more modules.

Returning back to FIG. 2, electrical connections are established between the PV modules in operation 205. For example, electrical leads extending from each PV module (such as elements 108a and 108b in FIG. 1) may be connected to two or more bus wires extending along the direction of the web. The leads may be welded (e.g., resistance welded, ultrasonic welded, laser welded), crimped, and/or soldered to the bus wires. In general, any structure that establishes electrical connection between two consecutive modules is referred to as a “module connector.” In the above example, a module connector includes portions of the bus wires extending between the two modules.

In certain embodiments, all PV modules in a row are electrically interconnected in parallel with each other using module connectors. Such a configuration ensures that no matter how many modules are provided in a set, the set will always provide the same operating voltage. FIG. 3B illustrates a schematic electrical diagram showing interconnection of three PV modules 304a-304c in a row interconnected with bus wires 325 and 327 in accordance with certain embodiments. The bus wires 325 and 327 are connected to respective electrical leads 321a-321c and 323a-323c of the modules 304a-304c. In this configuration, bus wires are used to combine and carry electrical currents from all modules without exposing module elements (e.g., PV cells) to high electrical currents.

In certain embodiments, module connectors are configured to limit an electrical current that can pass through the module connector. For example, if a set includes a number of PV modules that can generate a higher electrical current that can be safely passed through the module connectors, then the module connectors may be configured to limit the current passed by, e.g., temporally disconnecting one or more PV modules in this set. When a current falls within a safe range, the module connector may restore the original connection. It should be noted that PV modules may reach their peak current output only for a short period of time (e.g., highest solar intensity) during which one or more modules may be disconnected. This approach allows using smaller wires for electrical connectors, yet to connect a large number of PV modules.

A roll may also include bypass diodes, inverters, DC/DC converters, and/or various combinations of these components. A typical bypass diode is configured to prevent an electrical current from flowing back into the cells connected to the diode that are not generating electrical power, for example, due to shading, cell failure, and other reasons. An electrical resistance of the shaded cells is greater than that of the bypass diode, and the electrical current is passed (“shunted”) through the diode instead of passing through the cells, which could damage the cells in certain situations. Each photovoltaic cell may have a dedicated bypass diode or a group of cells may share one diode.

Furthermore, one or more DC/DC converters may be integrated into a roll. A DC/DC converter may be associated with one photovoltaic module or a set of modules. The DC/DC converter converts an input DC voltage into a higher or lower DC voltage level required by, for example, a central inverter. The central inverter may also be a part of the roll and be connected to a grid or other AC electrical systems. For example, several DC/DC converters can be connected to the central inverter by module connectors described above. The DC/DC converters allow each module (or each set of modules) to operate at its optimum current/voltage regime. The DC/DC converter may operate in a “buck” or “boost” mode, as appropriate. In certain embodiments, a roll includes a buck converter connected to a boost converter.

In certain embodiments, a module connector is configured to prevent electrical shorts when two modules interconnected by the connector are being separated during installation. For example, an installer may decide to cut off a set of modules from the roll while at least some modules in this roll are exposed to light. Often cutting is performed with sharp metal tools, such as a utility knife and/or a saw blade. Bus wires 325 and 327 may be spaced apart in the module connectors by a predetermined distance 329 such that the two wires can not be short by cutting tools during the installation. For example, a distance 329 may be at least about 2 inches.

The roll fabrication process may include providing sealing material between the first and second sheets to form an edge seal. In certain embodiments, an edge seal material containing a moisture getter or desiccant material such as a butyl based material. Sealing material may be dispensed onto the first sheet after establishing electrical connections in operation 205. Alternatively, sealing materials may be pre-arranged on and provided together with the first sheet and/or second sheet. In general, sealing material is distributed in the sealing area 306.

Returning to FIG. 2, the process 200 may proceed with positioning a second flexible sheet in operation 206. As explained above, if a backside sheet is used in operation 204 then the frontside sheet is provided in operation 206 or vice versa. Further, in certain embodiments, operation 206 may include folding a sheet provided in operation 204 as explained above.

The process 200 then continues with establishing a seal between the first and second sheets (or a fold of the first sheet) around each PV module in operation 208. A seal is configured to prevent moisture and other undesirable matter from ingressing into PV modules and damaging cells. Seals are maintained when modules are separated from one another. Further, seals allow module connectors to extend through the seals. In general, sealing may be provided by an adhesive bonding, a fusion bonding, a welding, a solder bond, or a mechanical fastening of the two sheets.

In certain embodiments, an assembly including both sheets and PV modules is passed through a laminator which subjects the assembly to heat and pressure in order to form a seal. In particular embodiments, any remaining voids within the seal may be under reduced pressure conditions (e.g., less than a typical atmospheric pressure of 760 mm Hg) and/or back-filed with dry gas (e.g., nitrogen).

FIG. 3C illustrates a schematic side cross-sectional view 320 of a cut-off area exemplifying sealing details in accordance with certain embodiments. Two PV modules 304a and 304b are positioned at a distance 305 from each other and sealed between the two sheets 302 and 312. The sealing areas are represented by 306a and 306b, which may include sealing material provided between the two sheets 302 and 312 and/or some form of bond between the sheets. The sealing areas 306a and 306b are shown outside of the cut-off area 310. In certain embodiments (not shown), as mentioned above, a portion of the sealing area may extend into the cut-off area and even merge with another sealing area as long as at least a portion of each sealing areas is outside of the cut-off area (i.e., between a cut-off area and a PV module).

The cut-off area 310 may be identified on the frontside sheet with two line markings extending across the row of the panels or more specifically across the web. An installer can separate two modules along any line that falls in between the two markings. For example, two line markings may be printed using an online inkjet printer. Alternatively, sealing seams may be used as identifiers of the cut-off area. Furthermore, an installer may rely on internal components of PV modules that are visible through the transparent frontside sheet to identify the cut-off area 310.

Also shown in this cross-sectional view is a module connector 308 extending between the two PV cells 304a and 304b. The module connector 308 passes through the sealing areas 306a and 306b without compromising the seals. It should be noted that the module connector 308 and the sealing areas 306a and 306b should be configured in such a way that the seals remain even when the modules are separated and the connector 308 is split into two pieces extending from each PV modules 304a and 304b and towards the cut edge. The two pieces need to be insulated, which may be performed with an array connector.

Returning to FIG. 2, the process 200 may continue with winding a web containing the PV modules into a roll in operation 210. A core of the roll establishes an initial (smallest) winding diameter, which may be determined by flexibility of the web. In particular embodiments, the web is sufficiently flexible to form a radius of at least 6 inches without any detectable damage to the web components (e.g., seals, electrical connections, PV cells). Other operations may include trimming the sides of the web, perforating a cut-off area to allow separating the panels by pulling them apart, and installing mounting features (e.g., metal rings in each of four corners of each module).

In certain embodiments, a roll is between about 12 inches and 60 inches wide or more specifically between about 24 inches and 48 inches. Such a roll may contain one, two, or more rows of the PV modules. Each row may include at least two modules or, more specifically, at least ten modules. In a particular example, a fabricated roll is at least 100 PV modules long.

While the fabrication techniques and design features described above are generally directed to a roll containing one row of PV modules, it should be noted that the techniques and features are applicable to a roll with multiple rows. In other embodiments, the rolls are not rolled but provided for installation either flat or folded.

### Installation of PV Arrays

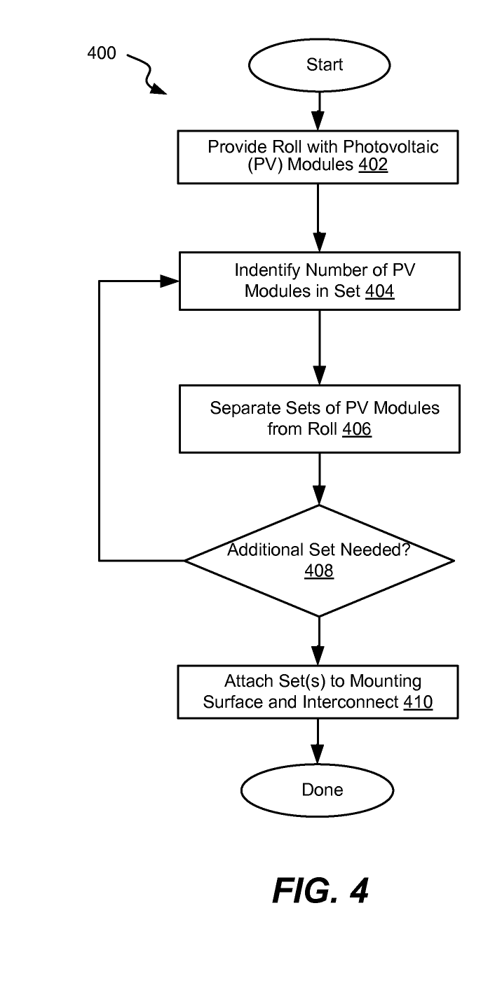

FIG. 4 is a process flowchart corresponding to one example of a technique for installing a PV array from a roll containing multiple flexible PV modules. The process 400 may start with providing one or more rolls containing flexible PV modules in operation 402. A roll may be wound on a core or a spool that allows handling large rolls without damaging PV modules.

The process 400 may continue with identifying a number of PV modules in one or more sets in operation 404. This may involve taking measurements of the installation area and determining any obstacles that may interfere with installation of PV modules. For example, in a rooftop installation, an installer may determine an area available for installation (e.g., an entire roof surface) and any obstacles, such ventilation pipes, HVAC units, and skylights. From these measurements, an installer may determine how a PV array can arranged such that an optimal number of PV sets is used. For example, an installer may choose to minimize the number of PV sets to have fewer electrical interconnections among the sets and fewer exposed edges. At the same, an installer may be constrained by a maximum size and shapes (for multi-row rolls) of sets that can be installed.

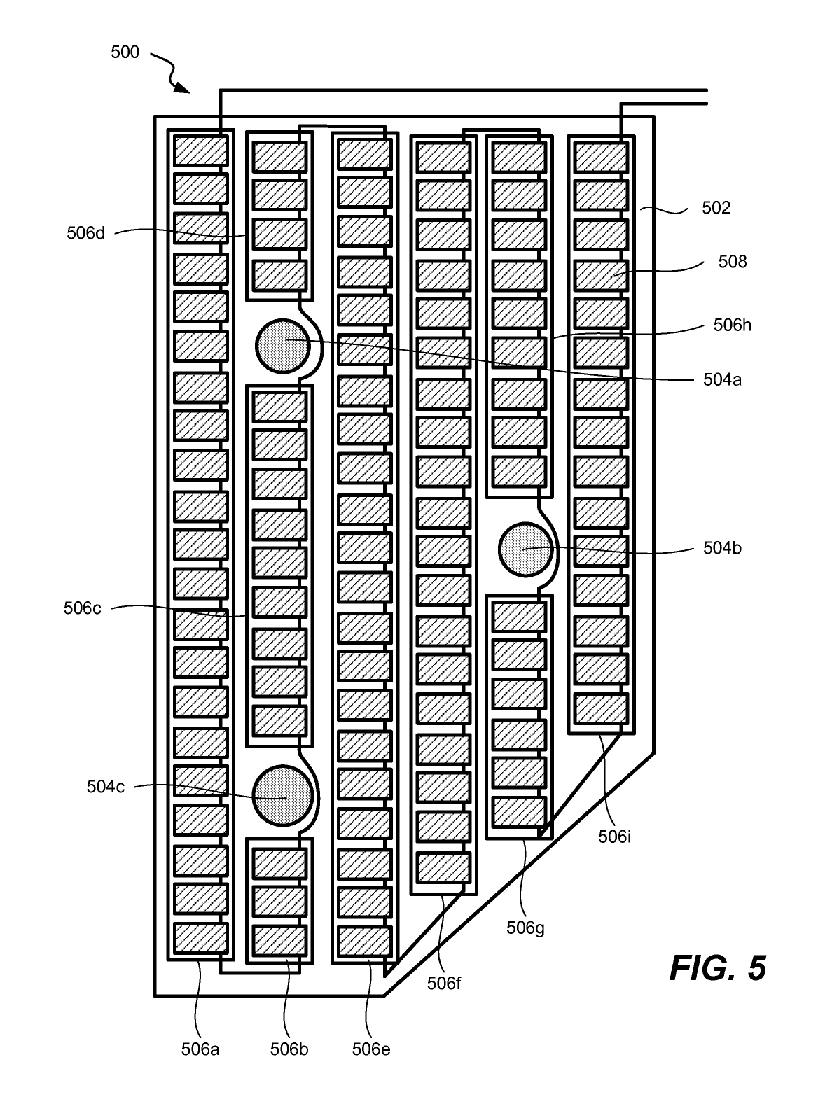

This operation will now be explained in the context of an example illustrated in FIG. 5. It shows a PV array 500 including nine sets 506a-506i of PV modules 508 installed in installation area 502, which may be a rooftop or other any other installation area. The installation area 502 is a rectangle with a cut corner and contains three obstacles 504a-504c where PV modules cannot be positioned. The first (leftmost) row of PV modules 508 in installation area 502 includes only one set 506a, which includes 21 modules 508. There are no obstacles along this row and an installer can use a single continuous set of modules to cover the area along the row. If for some other reasons installation of a single set containing 21 modules is not possible (e.g., a set is too heavy), then an installer may choose two use multiple sets to cover the area.

The area designated for the second row has two obstacles 504a and 504c. Therefore, a single set is not used for installation in this area. As shown in FIG. 5, the area may be covered with three separate sets: a set 506b containing only 3 panels, a set 506c containing 9 panels and a set 506c containing 4 panels.

The third row is the same as the first row and includes a single set 506e with 21 panels. The fourth row is slightly shorter than the first and third rows because of the cut corner. The area designated for the fourth row can only accommodate 19 panels as shown in FIG. 5. The fifth row is even shorter and contains an obstacle 504b. Therefore, two sets 506g and 506h with 6 and 9 panels respectively are used. Finally, the last 6 row includes a single set 506i of 15 panels. Overall, the array 500 shown in FIG. 5 contains 107 PV panels arranged into 9 sets. This example illustrates how substantial could be installation savings where an installer can work with integrated and interconnected PV sets instead of individual modules.

In certain embodiments (not shown), a roll includes multiple rows of PV modules. In this case, an installer may determine that a set should also include more than one row. For example, if a two-row roll is used for installation of an array 500 illustrated in FIG. 5, an installer may decide to combine sets 506a and 506c as well as sets 506e and 506f. This approach reduces a number of sets required for installation. In specific embodiment, an entire array may include only one set. For example, a roll may be provided with a 10×10 arrangement of 100 modules, with cut-off areas available in both directions of the roll. To cover a rectangular area, an installer may cut along multiple cut-off areas in two directions to form a set containing 8×6 modules, for example.

Returning back to FIG. 4, the process 400 may continue with operation 406 that involves separating sets of PV modules from the roll at the respective cut-off areas. Based on the example presented in FIG. 5, an installer may separate two sets of 21 panels, one set of 19 panels, one set of 15 panels, two sets of 9 panels, and single sets that include 3, 4, and 6 panels respectively. A separation operation 406 may include cutting with a sharp object (e.g., a utility knife, a saw blade), cutting with a heating device, tearing (e.g., when the sheets have partially cut scores), and other methods.

It should be noted that separating the PV panels will also result in separating a module connector that passes through a cut-off area. The separated portions of the module connectors will have exposed electrical leads (e.g., portions of the bus wires) at the cut-off seam. These leads may be insulated and/or used to form electrical connection to the set. For example, an array connector may be used for these purposes. Examples of array connectors and other electrical connectors are described in U.S. patent application Ser. No. [Attorney Docket MSOLP035/IDF149], which is filed concurrently and incorporated by reference herein.

An array connector may used to connect one set to another set (e.g., connect them in parallel), to connect one array to other elements of the overall solar system, or to connect two sets and at the same time connect them to other elements of the overall solar system. In certain embodiments, an array connector may be used to establish an electrical connection to one or more PV modules in the middle of the set (as oppose to end modules with exposed electrical leads). For example, a set may have more PV modules than can be supported by module connectors, i.e., the electrical current generated by all modules in the set exceeds capabilities of the module connectors. In this case, one or more array connectors may be used to electrically separate the set into sub-sets while maintaining them as mechanically integrated. Similarly an array connector may be used to connect two electrically unconnected but mechanically integrated sub-sets.

In addition to array connectors, exposed leads may be insulated using an insulating tape or a U-shape plastic channel that snuggly fits over the separated edge. Furthermore, these features may be used to enhance the seal along the separation line. For example, a U-shape channel may be filed with sealant material before fitting it over the edge. In this embodiment, the channel extends along the entire separation edge and not only the area with exposed leads.

Operations involve identifying a number of modules in a set and separating this number (and configuration, for multi-row sets) of modules from the roll may be repeated for additional sets to complete an array (block 408). At some point in the installation process 400, sets are attached to a mounting surface and electrically interconnected as described above (block 410). A mounting rack may be used to support the modules. The sets can be glued or otherwise mechanically fastened to the surface.

### CONCLUSION

Although the foregoing invention has been described in some detail for purposes of clarity of understanding, it will be apparent that certain changes and modifications may be practiced within the scope of the appended claims. It should be noted that there are many alternative ways of implementing the processes, systems and apparatus of the present invention. Accordingly, the present embodiments are to be considered as illustrative and not restrictive, and the invention is not to be limited to the details given herein.

What is claimed is:

1. A roll for fabricating a photovoltaic (PV) array, the roll comprising:
a flexible continuous backside sheet;
a transparent flexible continuous frontside sheet;
a row of PV modules extending along a length of the roll and comprising at least two PV modules disposed between the backside sheet and the frontside sheet, wherein each PV module is individually sealed;
a cut-off area located between the two PV modules, the cut-off area allowing separation of the two PV modules while maintaining the individual seals of each PV module; and
a module connector electrically interconnecting the two PV modules, wherein the module connector passes through the cut-off area.

2. The roll of claim 1, wherein the row comprises at least ten individually sealed and electrically interconnected PV modules, and wherein any number of the PV modules can be separated from the row without losing an individual seal of any of the PV modules.

3. The roll of claim 1, further comprising a second row of PV modules,
wherein the backside sheet and the frontside sheet provide individual seals to each PV module in the second row, and
wherein cut-off areas are located between the row and the second row.

4. The roll of claim 1, wherein the module connector interconnects the two PV modules in parallel.

5. The roll of claim 1, wherein the module connector is configured to limit an electrical current passing through the module connector.

6. The roll of claim 1, wherein the module connector is configured to prevent electrical shorts when the two PV modules are separated by cutting.

7. The roll of claim 6, wherein the module connector comprises two bus wires that are spaced apart by at least about 2 inches while passing through the cut-off area.

8. The roll of claim 1, wherein the cut-off area is at least about 2 inches wide.

9. The roll of claim 1, wherein the cut-off area comprises scores partially cut through the frontside sheet and the backside sheet.

10. The roll of claim 1, wherein the cut-off area is spaced apart from each of the two PV modules by at least 0.5 inches.

11. The roll of claim 1, further comprising a sealant disposed between the frontside sheet and the backside sheet around the entire perimeter of the PV modules at least in an area between the PV modules and the cut-off area.

12. The roll of claim 1, wherein the cut-off area is identified on the frontside sheet with two line markings extending across the row.

13. The roll of claim 1, wherein the transparent flexible continuous frontside sheet comprises one or more materials selected from the group consisting of polyethylene terephthalate (PET), polyethylene naphthalate (PEN), and a transparent metal oxide.

14. The roll of claim 13, wherein the transparent flexible continuous frontside sheet has a thickness of between about 3 mils and 30 mils.

15. The roll of claim 1, wherein the flexible continuous backside sheet comprises an aluminum sheet.

16. The roll of claim 15, wherein the aluminum sheet is offset from the cut-off area.

17. The roll of claim 15, wherein the flexible continuous backside sheet has a thickness of between about 5 mils and 80 mils.

18. The roll of claim 1, wherein each PV module is configured to provide electrical power output at a voltage of between about 10V and 30V at typical operating conditions.

19. The roll of claim 1, wherein the backside sheet is at least 12 inches wide.

20. The roll of claim 1, further comprising a plurality of mounting features.

21. The roll of claim 20, wherein each PV module has at least four mounting features located at each corner of the PV module.

22. The roll of claim 1, further comprising bypass diodes, inverters, and/or DC/DC converters.

23. A method of fabricating a roll comprising a row of multiple flexible photovoltaic (PV) modules, the method comprising:
providing a first flexible continuous sheet;
positioning at least two PV modules onto the first sheet;
installing a module connector to establish electrical connection between the two PV modules;
placing a second flexible continuous sheet over the first sheet and the two PV modules; and
establishing a seal between the first sheet and the second sheet around each of the two PV modules to individually insulate each PV module.

24. The method of claim 23, further comprising dispensing a sealant material onto the first sheet around a perimeter of each of the two PV cells prior to placing the second sheet.

25. The method of claim 23, wherein establishing the seal comprises laminating an assembly comprising the first sheet, the two PV panels, and the second sheet by applying heat and pressure to the assembly.

26. The method of claim 23, wherein positioning the two PV modules comprises arranging and electrically interconnecting individual PV cells in the two PV modules on the first sheet.

27. A method of installing a photovoltaic (PV) array using a roll, the method comprising:
(a) providing the roll;
(b) identifying a number of PV modules in a first set;
(c) identifying a cut-off area on the roll separated by the number of PV modules in the first set from a free end of the roll;
(d) separating the first set of PV modules from the roll; and
(e) installing the first set of PV modules into the PV array.

28. The method of claim 27, further comprising repeating (b)-(d) for additional sets to complete the PV array and electrically interconnecting at least two sets with an array connector.

29. The method of claim 28, wherein the array connector is configured to electrically connect to a portion of a module connector remaining on an end module of the first set of PV modules after separating of the first set of PV modules.

30. The method of claim 29, wherein the array connector is configured to electrically insulate the portion of the module connector.

31. The method of claim 27, further comprising electrically insulating at least a portion of a cut-off area an end module of the first set of PV modules.
